(19) United States
(12) Patent Application Publication
(10) Pub. No.: US 2023/0086080 A1
(43) Pub. Date: Mar. 23, 2023

(54) MAGNETOELECTRIC SPIN-ORBIT LOGIC DEVICE WITH A TOPOLOGICAL INSULATOR SUPERLATTICE

(71) Applicant: Intel Corporation, Santa Clara, CA (US)

(72) Inventors: Chia-Ching Lin, Portland, OR (US); Dmitri Evgenievich Nikonov, Beaverton, OR (US); Ian Alexander Young, Olympia, WA (US); John J. Plombon, Portland, OR (US); Hai Li, Portland, OR (US); Kaan Oguz, Portland, OR (US); Tanay A. Gosavi, Portland, OR (US); Emily Walker, Hillsboro, OR (US)

(73) Assignee: Intel Corporation, Santa Clara, CA (US)

(21) Appl. No.: 17/482,131

(22) Filed: Sep. 22, 2021

(51) Int. Cl. H01L 27/22; H01L 43/12; H01L 43/02

(52) U.S. Cl. CPC H01L 27/228; H01L 43/12; H01L 43/02; H01L 43/10

(57) ABSTRACT

In one embodiment, an apparatus includes a magnet, a first structure, and a second structure. The first structure includes a first conductive trace and a magnetoelectric material. The first conductive trace is coupled to an input voltage terminal, and the magnetoelectric material is coupled to the first conductive trace and the magnet. The second structure includes a superlattice structure and a second conductive trace. The superlattice structure includes one or more topological insulator materials. Moreover, the superlattice structure is coupled to the magnet and the second conductive trace, and the second conductive trace is coupled to an output voltage terminal.

### BACKGROUND

Magnetoelectric spin-orbit (MESO) logic is a type of spintronic logic that operates using the magnetoelectric effect in conjunction with the spin-orbit coupling effect (e.g., the coupling of an electron's inherent angular momentum with its translational orbital motion). For example, a MESO device uses magnetoelectric switching to convert an input voltage/charge into a magnetic spin state (e.g., charge-to-spin conversion) and further uses spin-orbit transduction to convert the magnetic spin state back into an output charge/voltage (e.g., spin-to-charge conversion). In order to form very-large-scale integration (VLSI) processors, MESO devices can be cascaded together, such that the output of one MESO device serves as the input to another MESO device. To support cascading, however, it is crucial for the output signal of a MESO device to be large enough to drive the input of another MESO device.

### BRIEF DESCRIPTION OF THE DRAWINGS

FIGS. 1A-B illustrate an example embodiment of a magnetoelectric spin-orbit (MESO) logic device in accordance with certain embodiments.

FIG. 2 illustrates a graph demonstrating the presence of the spin Hall effect in a topological insulator superlattice for a MESO device.

FIG. 3 illustrates another example embodiment of a MESO logic device.

FIG. 4 illustrates a top-down view of multiple cascaded MESO logic devices.

FIGS. 5A-H illustrate cross-section views of an example MESO device at various stages of fabrication.

FIG. 6 illustrates a flowchart for fabricating a MESO device in accordance with certain embodiments.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIG. 9 is a cross-sectional side view of an integrated circuit device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Spintronic logic refers to a class of integrated circuit devices that utilize a physical variable of magnetization or spin as a computing variable. Moreover, the physical variable used in spintronic logic can be non-volatile, which means the computing state is preserved when power to the integrated circuit is switched off. As a result, spintronic logic is energy efficient and enables ultralow power sleep states.

Magnetoelectric spin-orbit (MESO) logic refers to a class of spintronic logic that operates using the magnetoelectric effect in conjunction with the spin-orbit coupling effect (e.g., the coupling of an electron's inherent angular momentum with its translational orbital motion). For example, a MESO device uses magnetoelectric switching to convert an input charge/voltage into a magnetic spin state (e.g., charge-to-spin conversion) and further uses spin-orbit transduction to convert the magnetic spin state back into an output charge/voltage (e.g., spin-to-charge conversion). In this manner, a MESO device can be used to implement a logic device (e.g., a logic switch/gate) with a non-volatile logical state. For example, a logical state represented by an input charge/voltage can be converted into a (non-volatile) magnetic spin state, and the logical state can subsequently be read out by converting the magnetic spin state back into an output charge/voltage.

Accordingly, MESO devices can be used to implement logic circuitry (e.g., logic switches/gates) for scalable integrated circuits, analogous to CMOS (complementary metal-oxide-semiconductor) transistors. Compared to CMOS technology, however, MESO logic has superior energy efficiency (e.g., lower energy consumption for switching, which translates into lower operating voltage), higher integration density and efficiency (e.g., more logic functions per unit area, fewer devices required per logic function), and non-volatility (e.g., which counteracts leakage power and enables ultralow standby power).

One of the challenges associated with designing MESO logic, however, is ensuring that the output signal of one MESO device is large enough to drive the input of another MESO device. For example, MESO logic is typically implemented as a collection of cascaded MESO devices, where the output of one MESO device serves as the input to another MESO device. As a result, the output signal of each MESO device needs to be high enough to drive the input signal to the next MESO device. The output power of a MESO device is dependent on the efficiency of the spin-to-charge conversion readout, however, which has been a limiting factor for building higher-order majority gates, improving fan-out efficiency, and reducing the drive current required per gate of MESO logic. For example, during the spin-to-charge conversion, most spins dissipate at the interface of the spin orbit (SO) module and the magnet due to scattering, conductance mismatch, and lattice mismatch, which dramatically lowers the output signal.

In some cases, a material with a high spin-orbit coupling (SOC) effect—such as a topological insulator (TI)—may be used to improve the spin-to-charge conversion efficiency. For example, the spin orbit (SO) module of a MESO device may include a single layer of a topological insulator material for the spin-to-charge conversion readout. While a single topological insulator layer provides high spin-to-charge conversion efficiency—and high resistivity—it also has a short spin diffusion length (also referred to as “spin flip length”), which reduces the output voltage.

Accordingly, this disclosure presents embodiments of a MESO device with a topological insulator (TI) superlattice for the spin-to-charge conversion readout. The TI superlattice may include multiple alternating layers of two or more materials with different properties, such as multiple TI materials, or a TI material and a heavy metal, among other examples. In some embodiments, for example, the TI superlattice may include multiple different TI materials, such as a TI material with high resistivity (and high efficiency) and a TI material with low resistivity (and a long spin diffusion length). Alternatively, the TI superlattice may include a TI material with high resistivity (and high efficiency) and a heavy metal with low resistivity (and a long spin diffusion length).

Stacking multiple layers of materials in this manner (e.g., materials with different resistivity, efficiency, and spin diffusion length) increases the spin diffusion length and provides reasonable resistivity while preserving the surface states of the topological insulators, which results in higher output efficiency. As a result, the higher efficiency of the TI superlattice structure improves the fan-out efficiency of MESO logic.

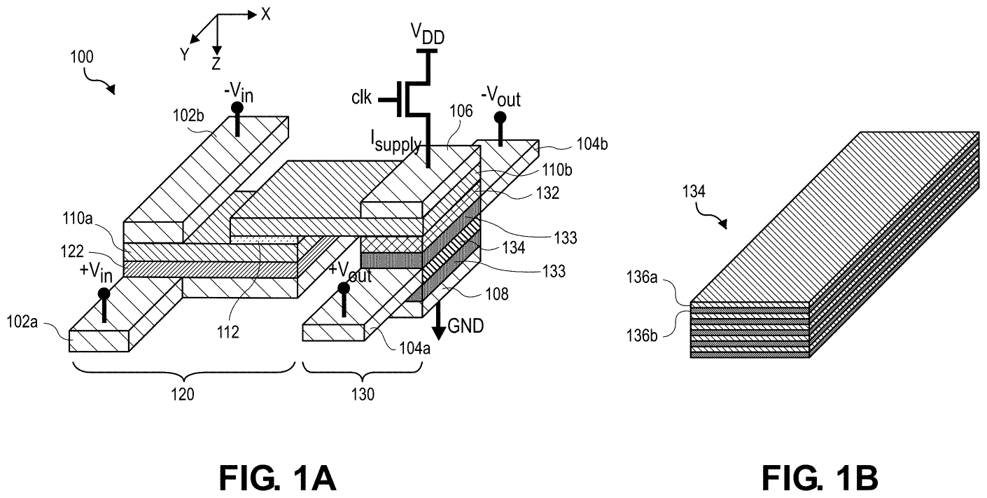

FIGS. 1A-B illustrate an example embodiment of a magnetoelectric spin-orbit (MESO) logic device 100 in accordance with certain embodiments. The overall layout of MESO device 100 is shown in FIG. 1A, and a more detailed view of the spin orbit coupling (SOC) stack 134 of MESO device 100 is shown in FIG. 1B. In the illustrated embodiment, MESO device 100 is a differential MESO device that can be used to implement a single MESO logic gate. Moreover, the spin orbit coupling stack or structure 134 of MESO device 100 includes a topological insulator (TI) superlattice for performing spin-to-charge conversion readouts, as described further below.

In the illustrated embodiment, MESO device 100 includes a magnet 110, a magnetoelectric (ME) conversion module 120, and a spin-orbit (SO) conversion module 130. MESO device 100 also includes interconnects or conductive traces coupled to terminals/electrodes for differential voltage inputs (+−Vᵢₙ) 102a-b, differential voltage outputs (+−Vₒᵤₜ) 104a-b, a power supply (V_{DD}) 106, and the ground (GND) 108. For example, conductive traces 102a-b are coupled to differential input voltage terminals (+−Vᵢₙ), conductive traces 104a-b are coupled to differential output voltage terminals (+−Vₒᵤₜ), conductive trace 106 is coupled to a power supply (V_{DD}) terminal, and conductive trace 108 is coupled to a ground (GND) terminal. In other embodiments, however, the differential input and output voltage terminals (+−Vᵢₙ and +−Vₒᵤₜ) may be replaced with a single input voltage terminal (Vᵢₙ) and a single output voltage terminal (Vₒᵤₜ), respectively (e.g., with a conductive trace coupling the input voltage terminal (Vᵢₙ) to the ME material 122, and a conductive trace coupling the SOC superlattice structure 134 to the output voltage terminal (Vₒᵤₜ)).

The ME module 120 performs charge-to-spin conversion to convert an electric charge current into spin (e.g., inducing a particular direction of magnetization on the magnet 110), and the SO module 130 performs spin-to-charge conversion to convert spin (e.g., the direction of magnetization induced on the magnet 110) back into an electric charge current, as described further below.

In the illustrated embodiment, the magnet 110 is formed by two ferromagnets 110a,b coupled via an insulating layer 112, which collectively function as a single magnet 110 (e.g., when the direction of magnetization changes on one of the ferromagnets 110a-b, it also changes on the other). Moreover, each ferromagnet 110a,b comprises a ferromagnetic material that retains the magnetization setting induced on it, which is to say that it is non-volatile.

The ME module 120 includes a structure (e.g., stack of layers) configured to convert an electric charge current into spin (e.g., magnetization). For example, the ME structure 120 is formed by the positive input voltage interconnect 102a (+Vᵢₙ), which in turn is coupled to a magnetoelectric (ME) material 122 (e.g., a magnetoelectric capacitor), which in turn is coupled to ferromagnet 110a, which in turn is coupled to the negative input voltage interconnect 102b (−Vᵢₙ). The ME material 122 has both ferroelectric properties (e.g., can be electrically polarized with or without an applied electric field) and magnetic properties (e.g., may exhibit surface spin polarization which can be switched under the application of an external electric field). In this manner, the ME structure 120 is configured as a capacitor, with magnet 110 and input voltage interconnect 102 serving as electrical plates surrounding the ME capacitor material 122.

When voltage is applied via the differential voltage inputs (+−Vᵢₙ) 102a-b, charge current (Iᵢₙ) flows across the ME material 122, which results in ferroelectric polarization in the ME material 122 and forms an electric field in the +−Z direction depending on the polarity of the current (Iᵢₙ). For example, when a positive input voltage (Vᵢₙ) is applied, the current flow is positive (e.g., in the +X direction) and an electric field forms in the −Z direction, with a positive charge adjacent to positive voltage input 102a (+Vᵢₙ) and a negative charge adjacent to ferromagnet 110a. By contrast, when a negative input voltage (Vᵢₙ) is applied, the current flow is negative (e.g., in the −X direction) and an electric field forms in the +Z direction, with a negative charge adjacent positive voltage input 102a (+Vᵢₙ) and a positive charge adjacent to ferromagnet 110a.

As the charge accumulates in the ME module 120, the spin of electrons in the ME material 122 at the interface with ferromagnet 110a become aligned to form surface spin polarization, forming a magnetic field. The direction of magnetization (spin) of the electrons in the surface spin polarization is defined by the direction of ferroelectric polarization within the ME material 122. As the magnetic field corresponding to the surface spin polarization is formed, it becomes exchange coupled with ferromagnet 110a, causing the magnetization in ferromagnet 110a to align with the magnetic field of the surface spin polarization, which in turn causes the same effect to occur in ferromagnet 110b. In this manner, the direction of magnetization of the magnet 110 can be switched based on the input current (Iᵢₙ). This setting of the direction of magnetization of the magnet 110 affects the output of the SO module 130, as described below.

The SO module 130 includes a structure (e.g., a stack of layers) configured to convert spin (e.g., the magnetization) back into an electric charge current. For example, the spin-orbit (SO) conversion structure 130 includes a power supply (V_{DD}) interconnect 106 coupled to ferromagnet 110b, which in turn is coupled—via a tunnel layer 132 (e.g., a tunneling barrier) and a spin coherent spacer layer 133—to a spin orbit coupling (SOC) structure 134 (e.g., a topological insulator (TI) superlattice), which in turn is coupled to a ground interconnect 108 via another spin coherent spacer layer 133.

Moreover, in some embodiments, the power supply (V_{DD}) is controlled via a transistor, with a source terminal coupled to a voltage supply (V_{DD}), a gate terminal coupled to a clock signal, and a drain terminal coupled to ferromagnet 110b (e.g., via power supply (V_{DD}) interconnect 106).

When voltage is applied via the power supply (V_{DD}) interconnect 106 (e.g., 100 mV), a supply charge current (I_{supply}) flows through ferromagnet 110b, causing the magnetization to produce a spin polarized current in which a substantial majority (e.g., greater than 80%) of electrons associated with the supply charge current (I_{supply}) will exhibit spin (e.g., magnetization) having a direction corresponding to the magnetization of ferromagnet 110b. Furthermore, the strength of the spin polarized current (e.g., the proportion of electrons that align with ferromagnet 110b) is proportional to the strength of the magnetization.

After the supply current passes through ferromagnet 110b and becomes a spin polarized current, the spin polarized current enters the tunnel layer 132 and spin coherent layer 133, which serve as a tunneling barrier to the spin orbit coupling (SOC) stack 134.

In particular, the role of the tunneling layer 132 is to ensure a high degree of spin polarization for the current flowing out of the ferromagnet 110b. For example, the tunneling layer 132 filters certain energies in the energy spectrum out of the current, which results in a higher degree of spin polarization for the current flowing out of the magnet 110b.

The current then flows from the tunnel layer 132 through the upper spin coherent layer spacer 133 (e.g., spacer layer with a sufficiently high spin diffusion length) and into the SOC structure 134. In particular, the spin coherent layers 133 serve as spacers on the top and bottom of the SOC structure 134. When the spin polarized current reaches the SOC structure 134, the spin-orbit effect transforms the vertical spin polarized current into spin charge current flowing horizontally, which produces an output voltage on the output voltage interconnects 104a,b (e.g., charging the input of the next MESO device). The output voltage creates a backflow of carriers, however, so the spin coherent spacers 133 are placed above and below the SOC structure 134 to prevent the backflow from flowing back into other components, such as the magnet 110 and/or the ground interconnect 108. In this manner, the spacers 133 constrain the backflow to the output interconnects 104a,b, which increases the output voltage. For example, the spin polarized current flows from ferromagnet 110b through the tunnel layer 132, the spacer 133, and into the spin orbit coupling stack 134, and then to the output voltage interconnects 104a,b, with minimal or no spin flow in the reverse direction.

The spin orbit coupling stack 134 has a strong or high spin-orbit effect, which is referred to as spin-orbit coupling. As a result, when the spin polarized current flows through the spin orbit coupling stack 134, due to the inverse spin-orbit coupling effect, the spin current converts into charge current (Iout), which produces an output voltage on the differential voltage outputs (+−Vₒᵤₜ) 104a-b.

This phenomenon is referred to as the inverse spin Hall effect (SHE), where a spin current transforms into a charge current when the spin current flows through a material with high spin-orbit interaction. By contrast, the standard spin Hall effect is a phenomenon where a charge current transforms into a spin current when the charge current flows through a material with high spin-orbit interaction. The directions of the spins are opposite at opposing lateral boundaries of the material, and the spin polarization is proportional to the current and changes sign when the direction of the current is reversed. Thus, the inverse spin Hall effect is simply the reverse of the spin Hall effect.

In the illustrated example, the SO module 130 is configured so that the direction of deflection of the electrons due to the spin Hall effect is either into or away from the differential voltage outputs (+−Vₒᵤₜ) 104a-b, which serve as an output of the MESO device 100. More particularly, the deflection of electrons produced by the spin Hall effect is along an axis (e.g., the Y axis) substantially perpendicular to both the supply charge current (I_{supply}) (e.g., the Z axis) and the spin polarized current corresponding to the direction of magnetization (e.g., the X axis), the two of which are substantially perpendicular to each other. Thus, the differential voltage outputs (+−Vₒᵤₜ) 104a-b are positioned substantially perpendicular to ferromagnet 110b (and associated direction of magnetization) and substantially perpendicular to the direction of the supply charge current (I_{supply}). Thus, the spin orbit coupling stack 134 deflects a majority of electrons into or away from the voltage outputs (+−Vₒᵤₜ) 104a-b, thereby resulting in an output current (Iout) that is proportional to the supply charge current (I_{supply}). In this manner, an output voltage is produced on the differential voltage outputs (+−Vₒᵤₜ) 104a-b, which serves as an output of the MESO device 100. A residual current may also pass through the spin orbit coupling stack 134 to ground 108.

In the illustrated example, the input current (Iᵢₙ) and the supply charge current (I_{supply}) may be provided during separate operations implemented at different times. More particularly, providing the input current (Iᵢₙ) may be compared to a write operation that sets or adjusts the direction of magnetization of the magnet 110. Further, providing the supply charge current (I_{supply}) may be compared to a read operation that produces the output current (Iout), which is proportional to the magnetization of the magnet 110 previously established during the write operation associated with the input current (Iᵢₙ).

In some embodiments, the value of the magnetization may be binary in which the magnet 110 is switched between one of two stable states. In such examples, the value of the magnetization is equal in both states but has an opposite sign (e.g., +1 in the first direction and —1 in the second direction). Thus, the corresponding output current (Iᵢₙ) is proportional to the supply current (I_{supply}) except that the sign or polarity may be changed. In such cases, MESO device 100 may be used as a signal repeater (with the magnetization set to +1), or as a signal inverter (with the magnetization set to −1).

In some embodiments, intermediate values for the magnetization may be achieved by controlling the position of a domain wall dividing distinct magnetic domains within the magnet 110 of the MESO device 100. Thus, in some examples, the magnetization of the magnet 110 may be controlled to a range of different values. The range may correspond to a plurality of discrete values or it may be substantially continuous between the steady states +1 and −1 described above.

As noted above, the respective voltages produced on the differential voltage outputs (+−Vₒᵤₜ) 104a-b serve as an output of the MESO device 100. However, MESO logic is typically implemented as a collection of cascaded MESO devices, where the output of one MESO device serves as the input to another MESO device. As a result, the output signals (+−Vₒᵤₜ) of the MESO device 100 must be large enough to drive the input signals (+−Vᵢₙ) 102a-b of another MESO device.

The output power of a MESO device 100 is dependent on the efficiency of the spin-to-charge conversion readout from the spin orbit coupling material 134, however, which has been a limiting factor in many solutions. For example, in some solutions, the spin-to-charge conversion is performed using a heavy metal (e.g., tungsten (W), tantalum (Ta), platinum (Pt)), which has very low spin-to-charge conversion efficiency (e.g., 4-15% efficiency).

On the other hand, a material with a high spin-orbit coupling (SOC) effect—such as a topological insulator (TI)—has high spin-to-charge conversion efficiency. For example, a topological insulator is a material that has conductive, spin-polarized surfaces with an interior that behaves as an insulator (e.g., a semiconducting or semi-metallic interior). As a result, electrons primarily move along the surface of the material and the band structure prevents electrons from backscattering, which results in high spin-to-charge conversion efficiency. Accordingly, a topological insulator (TI) could be used as the spin orbit coupling material 134 to improve the spin-to-charge conversion efficiency. However, while a single layer of a topological insulator material can provide high spin-to-charge conversion efficiency—and high resistivity—it also has a short spin diffusion length, which reduces the output voltage.

For example, the output voltage of MESO device 100 is represented by the following equation:

$$\frac{Δ V}{{I}_{supply}} = {P}_{FM} {θ}_{SOC} {ρ}_{SOC} {λ}_{sd} \frac{1}{{t}_{SOC} {w}_{SOC}} tanh ( \frac{{t}_{SOC}}{2 {λ}_{sd}} ) \qquad ( 1 )$$

where ΔV=differential output voltage (e.g., the difference between +−Vₒᵤₜ), ρ_{SOC}=spin resistivity of SOC material 134, λ_{sd}=spin diffusion length of SOC material 134 (e.g., the length of time in which spin diffuses in the SOC material 134), θ_{SOC}=spin-to-charge conversion efficiency, I_{supply}=charge current from supply voltage (V_{DD}), and P_{FM}=polarization of ferromagnet 110.

Based on the above equation, in order to increase the output voltage (ΔV), the spin orbit coupling layer 134 needs to be implemented by material(s) with high spin-to-charge conversion efficiency (θ_{SOC}), high resistivity (ρ_{SOC}), and a long spin diffusion length (λ_{sd}). While heavy metals have long spin diffusion lengths, they also have low resistivity and low spin-to-charge conversion efficiency. On the other hand, topological insulators have high resistivity and high spin-to-charge conversion efficiency, but they typically have short spin diffusion lengths, as the high resistivity makes it very easy for the spin to scatter.

Accordingly, as shown in FIG. 1B, the spin orbit coupling (SOC) stack 134 of MESO device 100 is implemented using a superlattice of materials 136a-b—such as topological insulators (TIs) and/or heavy metals—that collectively provide high spin-to-charge conversion efficiency (θ_{SOC}), long spin diffusion length (λ_{sd}), and reasonable resistivity (ρ_{SOC}), which results in a significant boost in the output voltage (ΔV) of MESO device 100.

In particular, the SOC superlattice 134 may include multiple alternating layers of two or more materials 136a-b with different properties, such as material(s) 136a with high resistivity (e.g., which may have high spin-to-charge conversion efficiency) and material(s) 136b with low resistivity (e.g., which may have a long spin diffusion length).

In some embodiments, for example, the SOC superlattice 134 may be a topological insulator (TI) superlattice implemented with multiple TI materials 136a,b—or a combination of TI material(s) and heavy metal(s)—with varying levels of resistivity. For example, the TI superlattice 134 may include a TI material 136a with high resistivity and a TI material 136b with low resistivity. Alternatively, or additionally, the TI superlattice 134 may include a TI material 136a with high resistivity and a heavy metal 136b with low resistivity. In this manner, the TI superlattice 134 achieves the high spin-to-charge efficiency of the high resistivity material and the long spin diffusion length of the low resistivity material—while also providing reasonable resistivity— which results in a significant boost in the output voltage (ΔV) of MESO device 100.

In some embodiments, a topological insulator with high resistance (e.g., superlattice material 136a) may be formed of a material that includes bismuth (Bi), selenium (Se), antimony (Sb), and/or tellurium (Te), such as BiSe, BiSbTe, and/or SbTe, among other examples.

Moreover, in some embodiments, a topological insulator with low resistance (e.g., superlattice material 136b) may be formed of a material that includes bismuth (Bi) and/or antimony (Sb), such as BiSb, among other examples.

Additionally, or alternatively, in some embodiments, a heavy metal with low resistance (e.g., superlattice material 136b) may be formed of a material that incudes platinum (Pt), tantalum (Ta), and/or tungsten (W), among other examples.

In other embodiments, however, the superlattice structure 134 may be implemented using any type, number, and/or combination of materials, across any number, size (e.g., thickness), and/or arrangement of layers (e.g., alternating periodically or periodically), whose properties collectively provide high spin-to-charge efficiency and long spin diffusion length. As an example, the SOC superlattice 134 may be implemented using other combinations of high-resistivity materials and low-resistivity materials.

The interconnects 102a-b, 104a-b, 106, 108 may be formed of any suitable conductive material (e.g., metal), such as a material that includes, for example, copper (Cu), silver (Ag), aluminum (Al), gold (Au), cobalt (Co), tungsten (W), tantalum (Ta), nickel (Ni), and/or graphene.

Moreover, electrodes/terminals associated with the input voltage (+−Vᵢₙ), output voltage (+−Vₒᵤₜ), power supply (V_{DD}), and/or ground (GND) connections may be formed of a material that includes, for example, strontium (Sr), ruthenium (Ru), oxygen (O), platinum (Pt), lanthanum (La), and/or manganese (Mn), such as SrRuO₃, Ru, Pt, and/or LaSrMnO₃, among other examples. In some embodiments, the thickness of the electrodes may range from 1-20 nanometers (nm).

Magnets 110a-b may be formed of any suitable magnetic material, such as a material that includes, for example, cobalt (Co), iron (Fe), nickel (Ni), gadolinium (Gd), and/or their alloys, such as CoFe and/or NiFe, or a magnetic oxide that includes, for example, lanthanum (La), strontium (Sr), manganese (Mn), oxygen (O), calcium (Ca), and/or titanium (TI), such as LaSrMnO₃, Co-doped or Fe-doped perovskite oxide (e.g., CaTiO₃), and/or any other type of oxide magnet, among other examples.

The insulating layer 112 may be formed of a material that includes, for example, magnesium (Mg), aluminum (Al), titanium (Ti), hafnium (Hf), silicon (Si), oxygen (O), and/or nitrogen (N), such as MgO, Al₂O₃, TiO₃, SiO₂, Si₃N₄, HfO₂, and/or any other oxide magnet, among other examples.

The magnetoelectric (ME) material 122 may be formed of any suitable magnetoelectric and/or multiferroic material (e.g., a multiferroic oxide), such as a material that includes, for example, bismuth (Bi), iron (Fe), oxygen (O), lutetium (Lu), lanthanum (La), titanium (Ti), lead (Pb), zirconium (Zr), terbium (Tb), magnesium (Mg), and/or niobium (Nb), such as bismuth ferrite (BFO) (e.g., BiFeO₃), LFO (e.g., LuFeO₂, LuFeO₃, LuFe₂O₄), La doped BiFeO₃, BiTiO₃, TbMnO₃, lead zirconate titanate (PZT), and/or lead magnesium niobate-lead titanate (PMN-PT), among other examples. In some embodiments, the thickness of the ME material 122 may range from 1-100 nanometers (nm).

The tunnel layer 132 may be formed of any suitable material for tunneling spin current from the magnet 110 to the SOC superlattice structure 134, such as a tunneling dielectric or tunneling oxide. In some embodiments, for example, the tunnel layer 132 may include magnesium (Mg), aluminum (Al), silicon (Si), titanium (Ti), and/or oxygen (O), such as MgO, AlO (e.g., Al₂O₃), SiO (e.g., SiO₂), and/or TiO, among other examples. Moreover, in some embodiments, the thickness of the tunnel layer 132 may range from 0.5-10 (nm).

In some embodiments, the spin coherent layers 133 may include copper (Cu), aluminum (Al), silver (Ag), gold (Au), graphene, and/or silicon (Si).

In some embodiments, the superlattice 134 may include 6-10 layers (e.g., alternating between the high-resistivity and low-resistivity materials 136a-b), and each layer may have a thickness ranging from 1 to 2 nanometers (nm). Moreover, in some embodiments, the high-resistivity material 136a may have a resistivity ranging from 3*10⁻⁵ Ω*m to 3*10⁻⁴ Ω*m, and the low-resistivity material 136b may have a resistivity ranging from 10⁻⁶ Ω*m to 10⁻⁵ Ω*m. In other embodiments, however, the number of layers, thickness per layer, and resistivities of the materials 136a-b may vary.

In some embodiments, the interconnect layers 102a-b, 104a-b, 106, 108 (e.g., copper) may have a resistivity up to 10⁻⁷ Ω*m. The spin coherent layer(s) 133 may have a resistivity ranging from 10⁻⁵ Ω*m to 10⁻⁴ Ω*m. The ferromagnet 110a,b may have a resistivity ranging from 10⁻⁶ Ω*m to 10⁻⁴ Ω*m, with a thickness ranging from 1 to 5 nm. The tunneling barrier 132 may have a resistance per unit area ranging from 1 to 100 Ω*μm², with a thickness ranging from 0.5 to 2 nm. In other embodiments, however, the thickness and resistivities of each layer may vary.

Further, in some embodiments, the resistivity of the various layers may satisfy the following guidelines:
(i) resistivity (low-resistance superlattice material 136b)*5<resistivity(high-resistance superlattice material 136a);
(ii) resistivity(low-resistance superlattice material 136a)*10<resistivity(spin coherent layer 133); and
(iii) resistivity(spin coherent layer 133)>30*resistivity(interconnect layers 102a-b, 104a-b, 106, 108)

Moreover, in various embodiments, MESO device 100 may be implemented using other types, numbers, and/or arrangements of components than shown in FIG. 1. For example, certain components of MESO device 100 may be added, replaced, omitted, and/or rearranged.

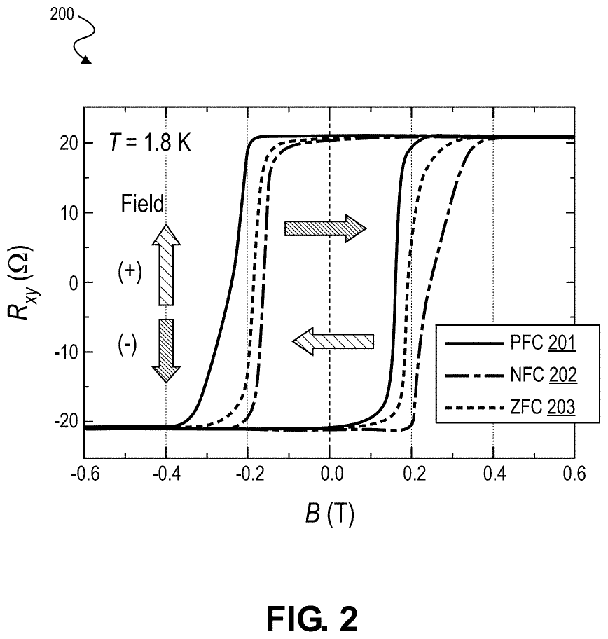

FIG. 2 illustrates a graph 200 demonstrating the presence of the spin Hall effect in a topological insulator superlattice with at least one high-resistance material and at least one low-resistance material (e.g., a high-resistance TI material and a low-resistance TI material, or a high-resistance TI material and a low-resistance heavy metal).

In particular, graph 200 shows the Hall resistance R_{xy}(Ω) of the TI superlattice as a function of the applied magnetic field B (T) for positive field cooling (PFC) 201, negative field cooling (NFC) 202, and zero field cooling (ZFC) 203 curves. The magnetic field is in the positive or negative direction for the PFC curve 201 and the NFC curve 202. As shown by graph 200, the TI superlattice demonstrates the presence of the spin Hall effect, which renders it suitable for performing spin-to-charge conversions in a MESO logic device (e.g., MESO device 100 of FIGS. 1A-B).

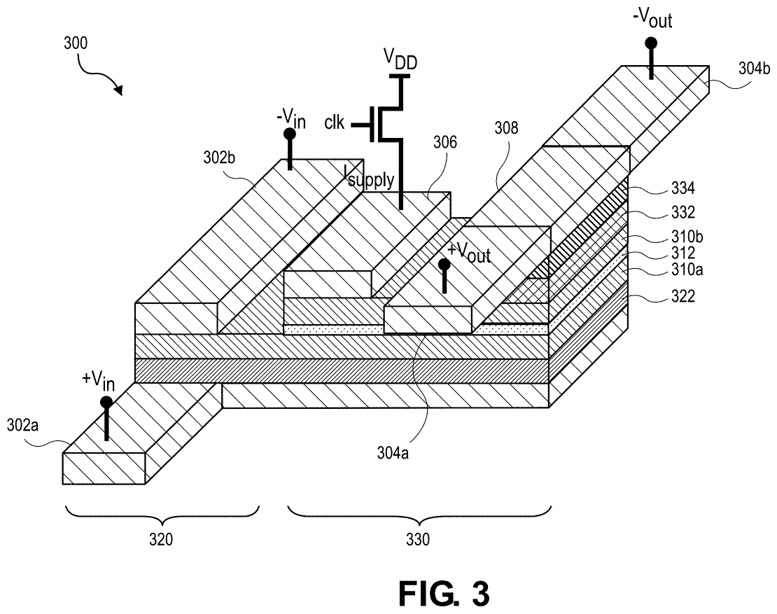

FIG. 3 illustrates another example embodiment of a magnetoelectric spin-orbit (MESO) logic device 300. In some embodiments, the components of MESO device 300 may be similar to those with corresponding reference numerals in MESO device 100 of FIGS. 1A-B. In MESO device 300, however, the components are arranged in a manner that improves the ease of integration (e.g., integration in a 300 millimeter (mm) wafer), as described further below. Moreover, although omitted from the figure for simplicity, the spin orbit coupling stack 334 of MESO device 300 may be implemented as a topological insulator (TI) superlattice for performing spin-to-charge conversion readouts. In some embodiments, for example, the spin orbit coupling stack 334 may be implemented using the TI superlattice 134 of FIG. 1B.

In the illustrated example, MESO device 300 includes a magnet 310, a magnetoelectric (ME) module 320, and a spin-orbit (SO) module 330, along with interconnects and/or electrodes to differential voltage inputs (+−Vᵢₙ) 302a-b, differential voltage outputs (+−Vₒᵤₜ) 304a-b, a power supply (V_{DD}) 306, and the ground (GND) 308.

The magnet 310 is formed by two magnets 310a,b coupled via an insulating layer 312, which collectively function as a single magnet 310.

The ME module 320 is configured as a capacitor, with magnet 310a and input voltage interconnects 302a-b (+−Vᵢₙ) serving as electrical plates separated by (and coupled to) a magnetoelectric (ME) material 322 (e.g., a magnetoelectric capacitor). For example, the ME module 320 includes a stack of layers arranged in the following order from bottom to top (e.g., based on the orientation shown in FIG. 3): the positive input voltage interconnect 302a (+Vᵢₙ), which in turn is coupled to the ME material 322, which in turn is coupled to the magnet 310a, which in turn is coupled to negative input voltage interconnect 302b (−Vᵢₙ). In particular, the upper surface of the positive input voltage interconnect 302a (+Vᵢₙ) is coupled to the lower surface of the ME material 322, the upper surface of the ME material 322 is coupled to the lower surface of magnet 310a, and the upper surface of magnet 310a is coupled to the lower surface of the negative input voltage interconnect 302b (−Vᵢₙ).

The SO module 330 includes a power supply (V_{DD}) interconnect 306 coupled to magnet 310b, which in turn is coupled to a tunnel layer 332, which is turn is coupled to a spin orbit coupling (SOC) stack 334 (e.g., a topological insulator (TI) superlattice), which in turn is coupled to differential output voltage interconnects 304a-b (+−Vₒᵤₜ) as well as a ground interconnect 308. Although not shown in the illustrated embodiment, the SO module 330 may also include spin coherent spacer layers above and below the SOC structure 334 (e.g., as described above in connection with spin coherent layer 133 of FIG. 1A).

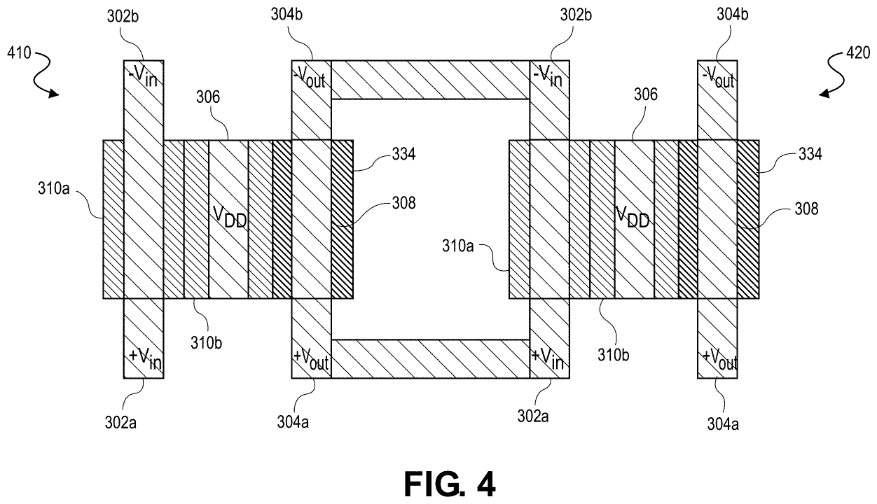

FIG. 4 illustrates a top-down view of multiple cascaded MESO logic devices 410, 420. In the illustrated example, MESO devices 410 and 420 are implemented using the design of MESO device 300 from FIG. 3. Moreover, MESO devices 410 and 420 are cascaded, such that the differential output voltage interconnects/terminals 304a-b (+−Vₒᵤₜ) of MESO device 410 are coupled to the differential input voltage interconnects/terminals 302a-b (+−Vᵢₙ) of MESO device 420. In this manner, the output of MESO device 410 drives the input of MESO device 420. In actual embodiments, any number of MESO logic devices may be cascaded using any desired arrangement. For example, the input voltage terminal(s) of each MESO device may be coupled to the output voltage terminal(s) of one or multiple MESO devices, and vice versa.

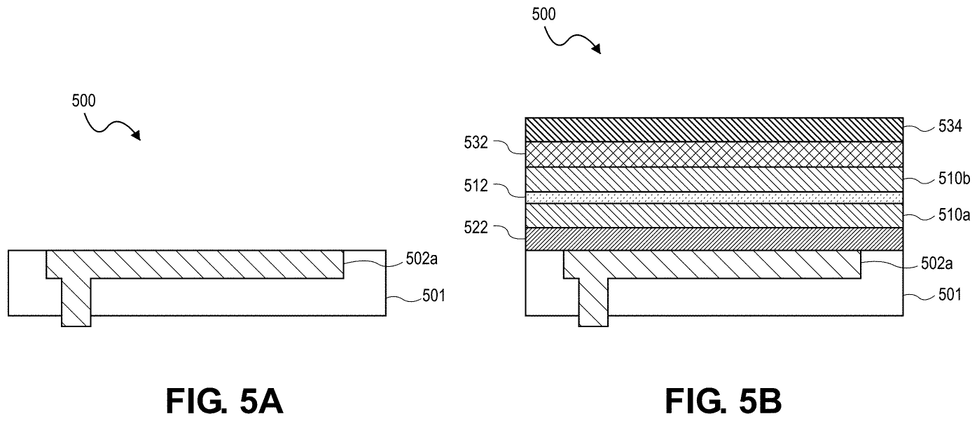

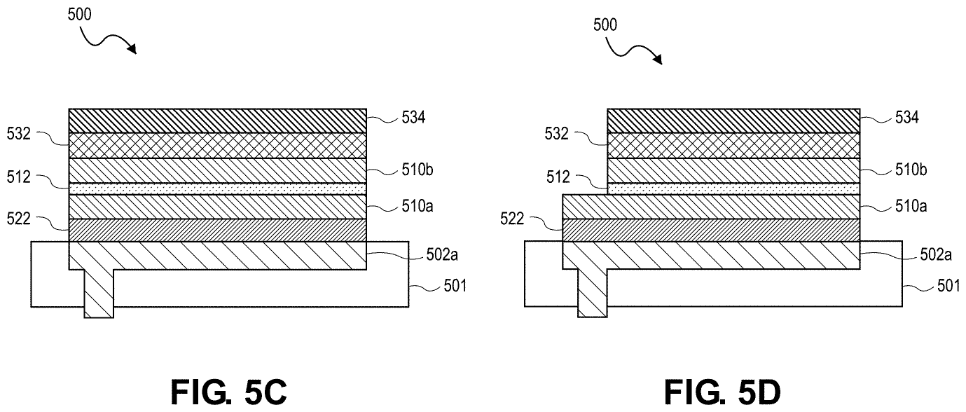

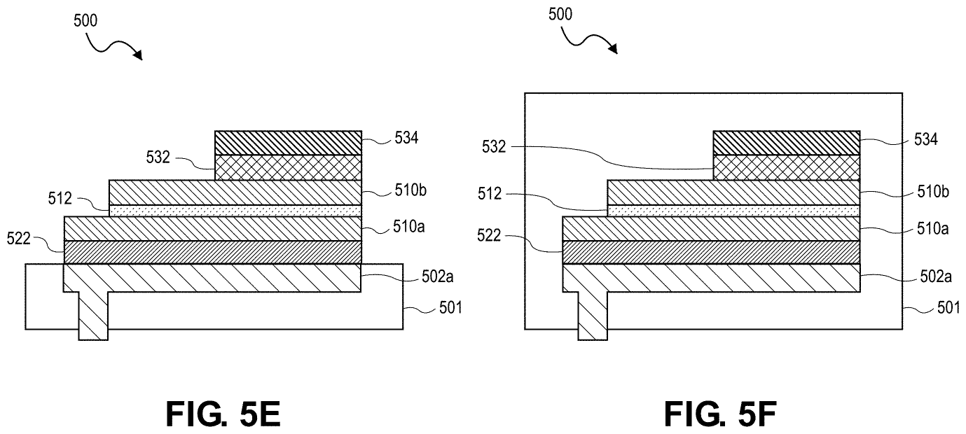

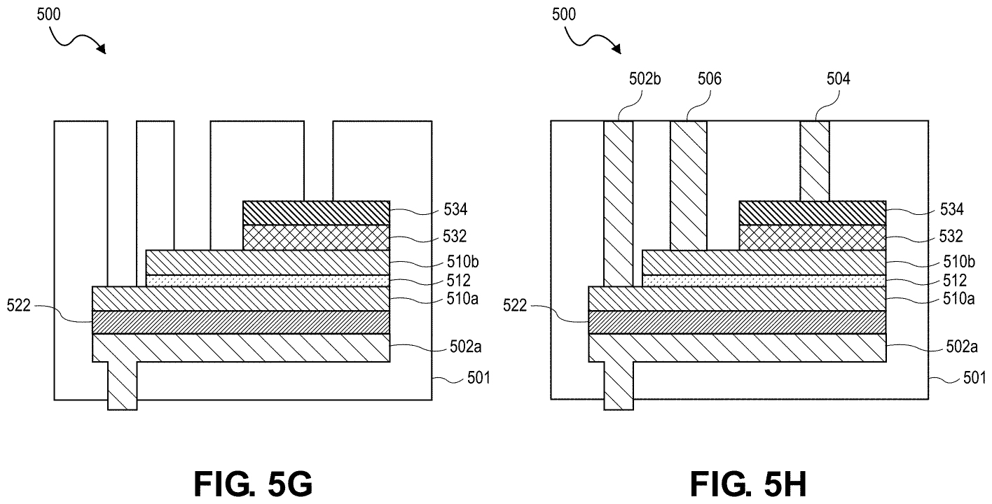

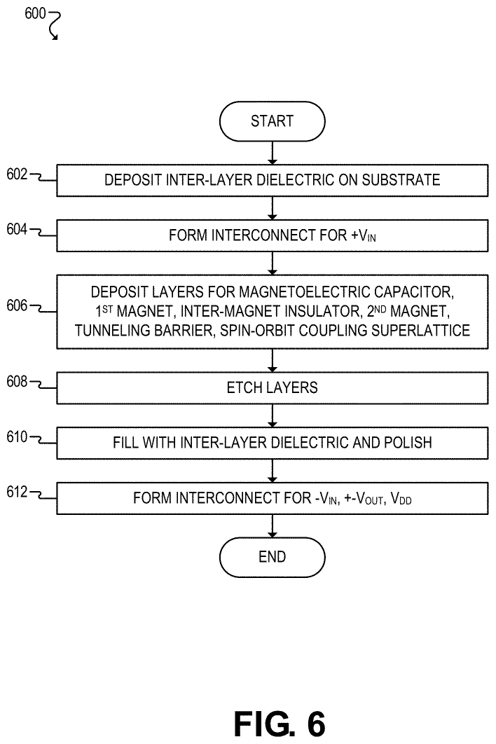

FIGS. 5A-H illustrate cross-section views of an example MESO device 500 at various stages of fabrication. Moreover, FIG. 6 illustrates a flowchart 600 for fabricating the MESO device 500 of FIGS. 5A-H. It will be appreciated in light of the present disclosure that flowchart 600 is only one example methodology for arriving at the example MESO device structures shown and described throughout this disclosure (e.g., MESO devices 100, 300, 500 of FIGS. 1, 3, 5A-H).

The steps of flowchart 600 may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 602, where an inter-layer dielectric (ILD) 501 is deposited on or above a substrate, as shown in FIG. 5A. The inter-layer dielectric (ILD) 501 may be formed of a dielectric and/or insulating material (e.g., a low-k dielectric), which may include, for example, silicon (Si), oxygen (O), fluorine (F), and/or carbon (C), such as oxides of silicon (e.g., silicon dioxide (SiO₂)), doped oxides of silicon, fluorinated oxides of silicon, carbon-doped oxides of silicon, and/or any other low-k dielectric materials and combinations thereof.

The flowchart then proceeds to block 604 to form an interconnect (e.g., one or more conductive traces) for the positive input voltage terminal (+Vᵢₙ) 502a, as shown in FIG. 5A. For example, the interconnect 502a is patterned in the ILD material 501 and then filled with a suitable interconnect material (e.g., one or more of the interconnect materials described throughout this disclosure). In some embodiments, for example, a via opening may be formed through the ILD 501 and then filled, and an interconnect layer may be patterned/etched above the via opening in the ILD and then filled.

The flowchart then proceeds to block 606 to deposit layers corresponding to the magnetoelectric (ME) material 522 (e.g., a magnetoelectric capacitor), 1^{st} magnet 510a, inter-magnet insulator 512 (e.g., insulating layer), 2^{nd} magnet 510b, tunnel layer 532 (e.g., tunneling barrier), and spin-orbit coupling (SOC) superlattice structure 534, as shown in FIG. 5B.

For example, the layers may be deposited from bottom to top in the order shown in FIG. 5B. In this manner, the ME material 522 is coupled/adjacent to the positive input voltage interconnect (+Vᵢₙ) 502a (below) and the 1^{st} magnet 510a (above). The 1^{st} magnet 510a is coupled/adjacent to the ME material 522 (below) and the negative input voltage interconnect (−Vᵢₙ) 502b (above), and further coupled to the 2^{nd} magnet 510b via the inter-magnet insulator 512 (above). The inter-magnet insulator 512 is coupled/adjacent to the 1^{st} magnet 510a (below) and the 2^{nd} magnet 510b (above). The 2^{nd} magnet 510b is coupled/adjacent to the inter-magnet insulator 512 (below) and the tunnel layer 532 (above). The tunnel layer 532 is coupled/adjacent to the 2^{nd} magnet 510b (below) and the SOC superlattice 534 (above). Finally, the SOC superlattice 534 is coupled/adjacent to the tunnel layer 532 (below). Although not shown in the illustrated embodiment, device 500 may also include spin coherent spacer layers above and below the SOC structure 534 (e.g., as described above in connection with spin coherent layer 133 of FIG. 1A).

In the illustrated example, the underlying structure of the SOC superlattice 534 is not shown for ease of illustration. It will be appreciated, however, that the SOC superlattice 534 may be formed using any of the superlattice structures shown and/or described throughout this disclosure, including the superlattice structure 134 of FIG. 1B. For example, the SOC superlattice 534 may be formed by depositing multiple alternating layers of different materials with various properties, such as a combination of high-resistance and low-resistance materials (e.g., topological insulators, metals), as described throughout this disclosure.

The flowchart then proceeds to block 608 to shape the MESO device 500 by etching away portions of various layers, as shown by FIGS. 5C, 5D, and 5E. For example, in FIG. 5C, the ME material 522, 1^{st} magnet 510a, inter-magnet insulator 512, 2^{nd} magnet 510b, tunnel barrier 532, and SOC superlattice 534 are etched on both sides to align with the interconnect layer 502a. In FIG. 5D, the inter-magnet insulator 512, 2^{nd} magnet 510b, tunnel barrier material 532, and SOC superlattice 534 are etched further on one side (e.g., left side), stopping on the bottom magnet 510a. In FIG. 5E, the tunnel barrier material 532 and SOC superlattice 534 are etched further on the same side as in FIG. 5D (e.g., left side), stopping on the top magnet 110b.

In this manner, the respective layers are staggered on one side (e.g., left side), such that (i) the interconnect 502a, ME material 522, and 1^{st} magnet 510a extend the furthest, followed by (ii) the inter-magnet insulator 512 and 2^{nd} magnet 510b, followed by (iii) the tunnel barrier material 532 and SOC superlattice 534.

The flowchart then proceeds to block 610, where the removed portions are filled with an inter-layer dielectric (ILD) 501, which is then polished, as shown in FIG. 5F.

The flowchart then proceeds to block 612 to form the remaining interconnects (e.g., conductive traces) for the negative input voltage terminal (−Vᵢₙ) 502b, the positive/negative output voltage terminals (+−Vₒᵤₜ) 504, and the power supply terminal (V_{DD}) 506, as shown in FIGS. 5G and 5H. In particular, via openings for the interconnects are formed in FIG. 5G, and the via openings are then filled and polished in FIG. 5H.

For example, in FIG. 5G, (i) a via opening for a conductive trace 502b to the negative input voltage terminal (−Vᵢₙ) is formed through the ILD 501 to the bottom magnet 510a; (ii) a via opening for conductive traces 504 to the differential output voltage terminals (+−Vₒᵤₜ) is formed through the ILD 501 to the SOC superlattice 534; and (iii) a via opening for a conductive trace 506 to the power supply terminal (V_{DD}) is formed through the ILD 501 to the top magnet 510b.

In FIG. 5H, the respective via openings are filled and polished using any suitable interconnect material (e.g., one or more of the interconnect materials described throughout this disclosure).

At this point, the flowchart may be complete. In some embodiments, however, the flowchart may restart and/or certain blocks may be repeated. For example, in some embodiments, the flowchart may restart at block 602 to continue fabricating another MESO device with the same or different design.

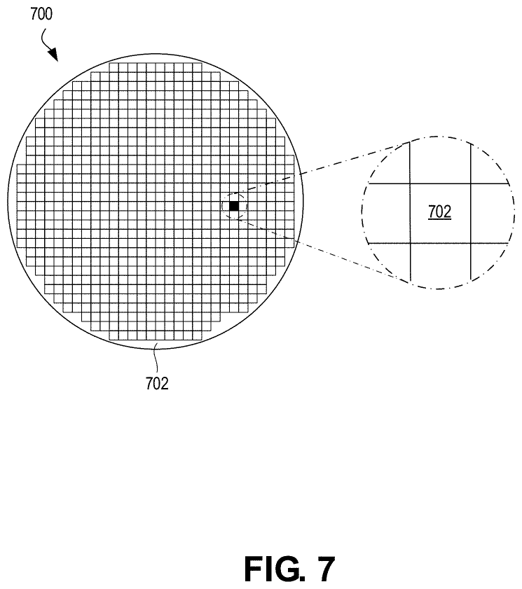

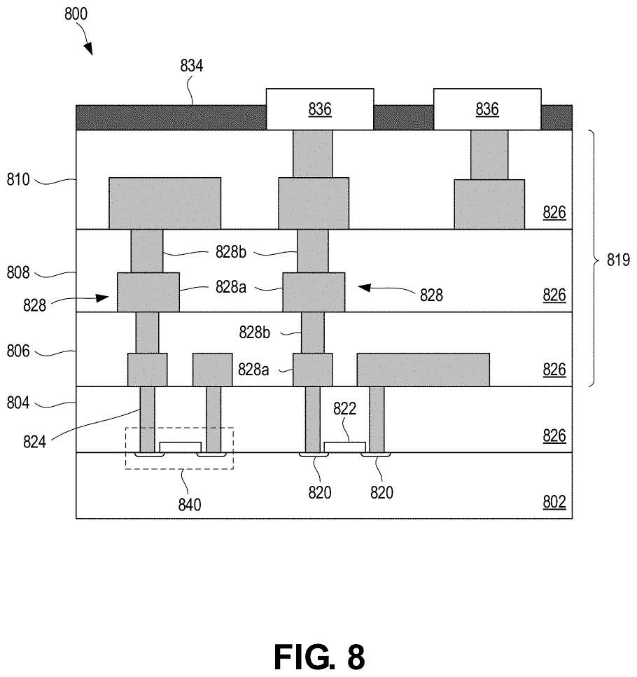

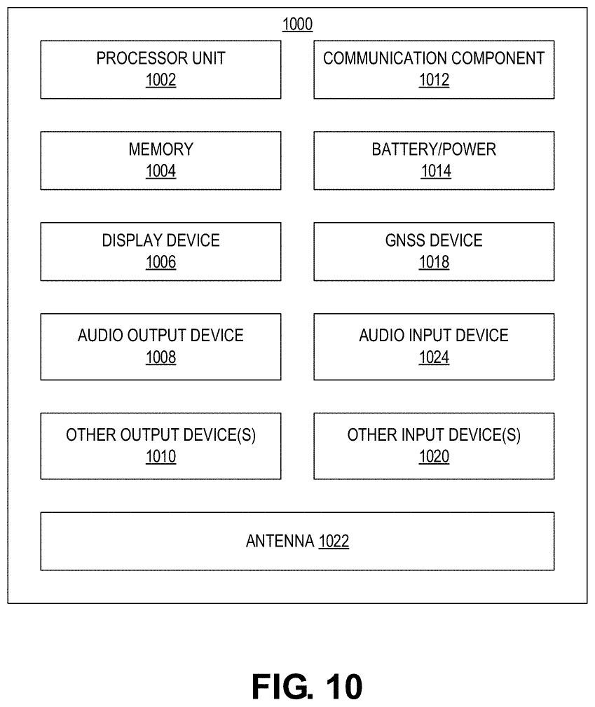

FIG. 7 is a top view of a wafer 700 and dies 702 that may be included in any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may be any of the dies disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1002 of FIG. 10) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include others of the dies, and the wafer 700 is subsequently singulated.

FIG. 8 is a cross-sectional side view of an integrated circuit device 800 that may be included in any of the embodiments disclosed herein (e.g., in any of the dies). One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components. The conductive contacts 836 may serve as any of the conductive contacts described throughout this disclosure.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836. These additional conductive contacts may serve as any of the conductive contacts described throughout this disclosure.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. These additional conductive contacts may serve as any of the conductive contacts described throughout this disclosure. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

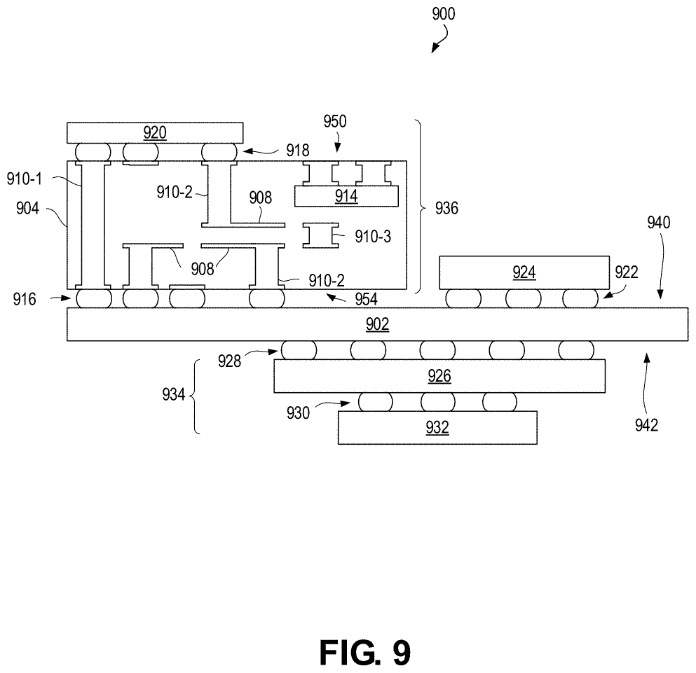

FIG. 9 is a cross-sectional side view of an integrated circuit device assembly 900 that may include any of the embodiments disclosed herein. In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may take the form of any suitable ones of the embodiments of the microelectronic assemblies 100 disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 916 may serve as the coupling components illustrated or described for any of the substrate assembly or substrate assembly components described herein, as appropriate.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the embodiments disclosed herein. For example, any suitable ones of the components of the electrical device 1000 may include one or more of the magnetoelectric spin orbital (MESO) devices (e.g., MESO devices 100, 300, 400, and/or 500), integrated circuit device assemblies 900, integrated circuit components 920, integrated circuit devices 800, or integrated circuit dies 702 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include other output device(s) 1010 (or corresponding interface circuitry, as discussed above). Examples of the other output device(s) 1010 may include an audio codec, a video codec, a printer, a wired or wireless transmitter for providing information to other devices, or an additional storage device.

The electrical device 1000 may include other input device(s) 1020 (or corresponding interface circuitry, as discussed above). Examples of the other input device(s) 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

### Example Embodiments

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an apparatus, comprising: a magnet; and a structure, comprising: a conductive trace coupled to an output voltage terminal; and a superlattice structure comprising one or more topological insulator materials, wherein the superlattice structure is coupled to the magnet and the conductive trace, and wherein the superlattice structure is to convert a spin current on the magnet into an output charge current on the conductive trace.

Example 2 includes the apparatus of Example 1, wherein the structure is a first structure and the conductive trace is a first conductive trace, and wherein the apparatus further comprises: a second structure, comprising: a second conductive trace coupled to an input voltage terminal; and a magnetoelectric material coupled to the second conductive trace and the magnet, wherein the magnetoelectric material is to convert an input charge current on the second conductive trace into the spin current on the magnet.

Example 3 includes the apparatus of Example 2, wherein the superlattice structure further comprises a plurality of alternating layers, wherein the plurality of alternating layers alternate between a plurality of materials, wherein the plurality of materials comprises: the one or more topological insulator materials; and one or more metals.

Example 4 includes the apparatus of Example 3, wherein: the one or more topological insulator materials comprise: bismuth and selenium; bismuth, antimony, and tellurium; or antimony and tellurium; and the one or more metals comprise platinum, tantalum, or tungsten.

Example 5 includes the apparatus of Example 3, wherein: the one or more topological insulator materials have a high resistance; and the one or more metals have a low resistance.

Example 6 includes the apparatus of Example 2, wherein: the one or more topological insulator materials comprise a plurality of topological insulator materials; and the superlattice structure further comprises a plurality of alternating layers, wherein the plurality of alternating layers alternate between the plurality of topological insulator materials, wherein the plurality of topological insulator materials comprises: a first topological insulator material having a high resistance; and a second topological insulator material having a low resistance.

Example 7 includes the apparatus of Example 6, wherein: the first topological insulator material comprises: bismuth and selenium; bismuth, antimony, and tellurium; or antimony and tellurium; and the second topological insulator material comprises bismuth and antimony.

Example 8 includes the apparatus of Example 2, wherein the first structure further comprises: a tunnel layer between the magnet and the superlattice structure, wherein the tunnel layer is to tunnel the spin current from the magnet to the superlattice structure, wherein the tunnel layer comprises: magnesium and oxygen; aluminum and oxygen; or silicon and oxygen.

Example 9 includes the apparatus of Example 2, wherein the magnetoelectric material comprises: bismuth, iron, and oxygen; lutetium, iron, and oxygen; bismuth, titanium, and oxygen; lanthanum, bismuth, iron, and oxygen; or terbium, manganese, and oxygen.

Example 10 includes the apparatus of Example 2, wherein the magnet comprises a first magnet and a second magnet coupled via a dielectric layer.

Example 11 includes the apparatus of Example 10, wherein: the first magnet and the second magnet comprise: cobalt, iron, or nickel; lanthanum, strontium, manganese, and oxygen; or calcium, titanium, and oxygen; and the dielectric layer comprises: magnesium and oxygen; aluminum and oxygen; titanium and oxygen; silicon and oxygen; silicon and nitrogen; or hafnium and oxygen.

Example 12 includes the apparatus of Example 2, wherein the first structure further comprises: a third conductive trace coupled to a supply voltage terminal and the magnet.

Example 13 includes the apparatus of Example 2, wherein: the output voltage terminal comprises a plurality of differential output voltage terminals; the first conductive trace comprises a plurality of first conductive traces coupled to the plurality of differential output voltage terminals; the input voltage terminal comprises a plurality of differential input voltage terminals; and the second conductive trace comprises a plurality of second conductive traces coupled to the plurality of differential input voltage terminals.

Example 14 includes the apparatus of Example 2, wherein the apparatus is a magnetoelectric spin-orbit (MESO) device, wherein the MESO device comprises the magnet, the first structure, and the second structure.

Example 15 includes an integrated circuit die, comprising: a plurality of logic devices, wherein each logic device comprises: a magnet; a first structure, comprising: a first conductive trace coupled to an input voltage terminal; and a magnetoelectric material coupled to the first conductive trace and the magnet, wherein the magnetoelectric material is to convert an input charge current on the first conductive trace into a spin current on the magnet; and a second structure, comprising: a superlattice structure comprising one or more topological insulator materials, wherein the superlattice structure is coupled to the magnet and a second conductive trace, and wherein the superlattice structure is to convert the spin current on the magnet into an output charge current on the second conductive trace; and the second conductive trace coupled to an output voltage terminal; wherein the input voltage terminal of at least some of the plurality of logic devices is coupled to the output voltage terminal of one or more other logic devices.

Example 16 includes the integrated circuit die of Example 15, wherein the superlattice structure further comprises a plurality of alternating layers, wherein the plurality of alternating layers alternate between a plurality of materials, wherein the plurality of materials comprises: the one or more topological insulator materials; and one or more metals.

Example 17 includes the integrated circuit die of Example 16, wherein: the one or more topological insulator materials comprise: bismuth and selenium; bismuth, antimony, and tellurium; or antimony and tellurium; and the one or more metals comprise platinum, tantalum, or tungsten.

Example 18 includes the integrated circuit die of Example 15, wherein: the one or more topological insulator materials comprise a plurality of topological insulator materials; and the superlattice structure further comprises a plurality of alternating layers, wherein the plurality of alternating layers alternate between the plurality of topological insulator materials.

Example 19 includes the integrated circuit die of Example 18, wherein the plurality of topological insulator materials comprises a first topological insulator material and a second topological insulator material, wherein: the first topological insulator material comprises: bismuth and selenium; bismuth, antimony, and tellurium; or antimony and tellurium; and the second topological insulator material comprises bismuth and antimony.

Example 20 includes the integrated circuit die of Example 15, wherein the magnet comprises a first magnet and a second magnet coupled via a dielectric layer.

Example 21 includes the integrated circuit die of Example 15, wherein the second structure further comprises: a tunnel layer between the magnet and the superlattice structure, wherein the tunnel layer is to tunnel the spin current from the magnet to the superlattice structure.

Example 22 includes the integrated circuit die of Example 21, wherein: the magnet comprises: cobalt, iron, or nickel; lanthanum, strontium, manganese, and oxygen; or calcium, titanium, and oxygen; the tunnel layer comprises: magnesium and oxygen; aluminum and oxygen; or titanium and oxygen; the magnetoelectric material comprises: bismuth, iron, and oxygen; lutetium, iron, and oxygen; bismuth, titanium, and oxygen; lanthanum, bismuth, iron, and oxygen; or terbium, manganese, and oxygen.

Example 23 includes a method, comprising: forming a first conductive trace in one or more dielectric layers on a substrate; forming a magnetoelectric capacitor coupled to the first conductive trace; forming a magnet adjacent to the magnetoelectric capacitor; forming a tunnel barrier adjacent to the magnet; forming a superlattice structure adjacent to the tunnel barrier; and forming a second conductive trace coupled to the superlattice structure.

Example 24 includes the method of Example 23, wherein forming the superlattice structure adjacent to the tunnel barrier comprises: depositing a plurality of alternating layers adjacent to the tunnel barrier, wherein the plurality of alternating layers alternate between a plurality of materials, wherein the plurality of materials comprises: one or more topological insulator materials and one or more metals; or a plurality of topological insulator materials.

Example 25 includes the method of Example 23, wherein forming the magnet adjacent to the magnetoelectric capacitor comprises: forming a first magnet adjacent to the magnetoelectric capacitor; forming a dielectric layer adjacent to the first magnet; and forming a second magnet adjacent to the dielectric layer.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

The terms “substantially,” “close,” “approximately,” “near,” and “about” may refer to being within +/−10% of a target value unless otherwise specified.

Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In some embodiments, the phrase “A is located on B” or the phrase “A is adjacent to B” means that at least a part of A is in direct physical contact or indirect physical contact (having one or more other features between A and B) with at least a part of B. Moreover, the phrase “B is between A and C” means that at least part of B is in or along a space separating A and C and that the at least part of B is in direct or indirect physical contact with A and C.

The terms “coupled” and “connected” may refer to either a direct or indirect connection, such as a direct electrical, mechanical, or magnetic connection, or an indirect connection through one or more passive or active intermediary elements, components, or devices.

The phrases “in an embodiment,” “according to some embodiments,” “in accordance with embodiments,” “in embodiments,” and the like may each refer to one or more of the same or different embodiments.

The terms “comprises,” “comprising,” “includes,” “including,” “having” and the like specify the presence of the stated elements (e.g., features, components, materials, steps, operations) but do not preclude the presence or addition of one or more other elements.

The phrase “and/or” as used herein refers to and encompasses any and all possible combinations of one or more of the associated listed items.

The singular forms “a,” “an,” and “the” are intended to include the plural forms as well, unless the context clearly indicates otherwise. For example, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

As used herein, the term “module” may refer to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

The terms “circuit” or “circuitry,” as used in any embodiment herein, are functional and may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smart phones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

For purposes of some embodiments, the transistors in various circuits and logic blocks described herein may be metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BIT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.). Moreover, in some embodiments, spintronic logic devices (e.g., magnetoelectric spin-orbit (MESO) logic devices) may be used in addition to, or as an alternative to, MOS transistors.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

In the foregoing description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure.

It is to be appreciated that the layers and materials described above are typically formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, the structures depicted above may be fabricated on underlying lower level back end of line (BEOL) interconnect layers.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the art. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

The disclosed embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combination thereof.

1. An apparatus, comprising:
a magnet; and
a structure, comprising:
a conductive trace coupled to an output voltage terminal; and
a superlattice structure comprising one or more topological insulator materials, wherein the superlattice structure is coupled to the magnet and the conductive trace, and wherein the superlattice structure is to convert a spin current on the magnet into an output charge current on the conductive trace.

2. The apparatus of claim 1, wherein the structure is a first structure and the conductive trace is a first conductive trace, and wherein the apparatus further comprises:
a second structure, comprising:
a second conductive trace coupled to an input voltage terminal; and
a magnetoelectric material coupled to the second conductive trace and the magnet, wherein the magnetoelectric material is to convert an input charge current on the second conductive trace into the spin current on the magnet.

3. The apparatus of claim 2, wherein the superlattice structure further comprises a plurality of alternating layers, wherein the plurality of alternating layers alternate between a plurality of materials, wherein the plurality of materials comprises:
the one or more topological insulator materials; and
one or more metals.

4. The apparatus of claim 3, wherein:
the one or more topological insulator materials comprise:
bismuth and selenium;
bismuth, antimony, and tellurium; or
antimony and tellurium; and
the one or more metals comprise platinum, tantalum, or tungsten.

5. The apparatus of claim 3, wherein:
the one or more topological insulator materials have a high resistance; and
the one or more metals have a low resistance.

6. The apparatus of claim 2, wherein:
the one or more topological insulator materials comprise a plurality of topological insulator materials; and
the superlattice structure further comprises a plurality of alternating layers, wherein the plurality of alternating layers alternate between the plurality of topological insulator materials, wherein the plurality of topological insulator materials comprises:
a first topological insulator material having a high resistance; and
a second topological insulator material having a low resistance.

7. The apparatus of claim 6, wherein:
the first topological insulator material comprises:
bismuth and selenium;
bismuth, antimony, and tellurium; or
antimony and tellurium; and
the second topological insulator material comprises bismuth and antimony.

8. The apparatus of claim 2, wherein the first structure further comprises:
a tunnel layer between the magnet and the superlattice structure, wherein the tunnel layer is to tunnel the spin current from the magnet to the superlattice structure, wherein the tunnel layer comprises:
magnesium and oxygen;
aluminum and oxygen; or
silicon and oxygen.

9. The apparatus of claim 2, wherein the magnetoelectric material comprises:
bismuth, iron, and oxygen;
lutetium, iron, and oxygen;
bismuth, titanium, and oxygen;
lanthanum, bismuth, iron, and oxygen; or
terbium, manganese, and oxygen.

10. The apparatus of claim 2, wherein the magnet comprises a first magnet and a second magnet coupled via a dielectric layer.

11. The apparatus of claim 10, wherein:
the first magnet and the second magnet comprise:
cobalt, iron, or nickel;
lanthanum, strontium, manganese, and oxygen; or
calcium, titanium, and oxygen; and
the dielectric layer comprises:
magnesium and oxygen;
aluminum and oxygen;
titanium and oxygen;
silicon and oxygen;
silicon and nitrogen; or
hafnium and oxygen.

12. The apparatus of claim 2, wherein the first structure further comprises:
a third conductive trace coupled to a supply voltage terminal and the magnet.

13. The apparatus of claim 2, wherein:
the output voltage terminal comprises a plurality of differential output voltage terminals;
the first conductive trace comprises a plurality of first conductive traces coupled to the plurality of differential output voltage terminals;
the input voltage terminal comprises a plurality of differential input voltage terminals; and
the second conductive trace comprises a plurality of second conductive traces coupled to the plurality of differential input voltage terminals.

14. The apparatus of claim 2, wherein the apparatus is a magnetoelectric spin-orbit (MESO) device, wherein the MESO device comprises the magnet, the first structure, and the second structure.

15. An integrated circuit die, comprising:
a plurality of logic devices, wherein each logic device comprises:
a magnet;
a first structure, comprising:
a first conductive trace coupled to an input voltage terminal; and
a magnetoelectric material coupled to the first conductive trace and the magnet, wherein the magnetoelectric material is to convert an input charge current on the first conductive trace into a spin current on the magnet; and
a second structure, comprising:
a superlattice structure comprising one or more topological insulator materials, wherein the superlattice structure is coupled to the magnet and a second conductive trace, and wherein the superlattice structure is to convert the spin current on the magnet into an output charge current on the second conductive trace; and
the second conductive trace coupled to an output voltage terminal;
wherein the input voltage terminal of at least some of the plurality of logic devices is coupled to the output voltage terminal of one or more other logic devices.

16. The integrated circuit die of claim 15, wherein the superlattice structure further comprises a plurality of alternating layers, wherein the plurality of alternating layers alternate between a plurality of materials, wherein the plurality of materials comprises:
the one or more topological insulator materials; and
one or more metals.

17. The integrated circuit die of claim 16, wherein:
the one or more topological insulator materials comprise:
bismuth and selenium;
bismuth, antimony, and tellurium; or
antimony and tellurium; and
the one or more metals comprise platinum, tantalum, or tungsten.

18. The integrated circuit die of claim 15, wherein:
the one or more topological insulator materials comprise a plurality of topological insulator materials; and
the superlattice structure further comprises a plurality of alternating layers, wherein the plurality of alternating layers alternate between the plurality of topological insulator materials.

19. The integrated circuit die of claim 18, wherein the plurality of topological insulator materials comprises a first topological insulator material and a second topological insulator material, wherein:
the first topological insulator material comprises:
bismuth and selenium;
bismuth, antimony, and tellurium; or
antimony and tellurium; and
the second topological insulator material comprises bismuth and antimony.

20. The integrated circuit die of claim 15, wherein the magnet comprises a first magnet and a second magnet coupled via a dielectric layer.

21. The integrated circuit die of claim 15, wherein the second structure further comprises:
a tunnel layer between the magnet and the superlattice structure, wherein the tunnel layer is to tunnel the spin current from the magnet to the superlattice structure.

22. The integrated circuit die of claim 21, wherein:
the magnet comprises:
cobalt, iron, or nickel;
lanthanum, strontium, manganese, and oxygen; or
calcium, titanium, and oxygen;
the tunnel layer comprises:
magnesium and oxygen;
aluminum and oxygen; or
titanium and oxygen;
the magnetoelectric material comprises:
bismuth, iron, and oxygen;
lutetium, iron, and oxygen;
bismuth, titanium, and oxygen;
lanthanum, bismuth, iron, and oxygen; or
terbium, manganese, and oxygen.

23. A method, comprising:
forming a first conductive trace in one or more dielectric layers on a substrate;
forming a magnetoelectric capacitor coupled to the first conductive trace;
forming a magnet adjacent to the magnetoelectric capacitor;
forming a tunnel barrier adjacent to the magnet;
forming a superlattice structure adjacent to the tunnel barrier; and
forming a second conductive trace coupled to the superlattice structure.

24. The method of claim 23, wherein forming the superlattice structure adjacent to the tunnel barrier comprises:
depositing a plurality of alternating layers adjacent to the tunnel barrier, wherein the plurality of alternating layers alternate between a plurality of materials, wherein the plurality of materials comprises:
one or more topological insulator materials and one or more metals; or
a plurality of topological insulator materials.

25. The method of claim 23, wherein forming the magnet adjacent to the magnetoelectric capacitor comprises:
forming a first magnet adjacent to the magnetoelectric capacitor;
forming a dielectric layer adjacent to the first magnet; and
forming a second magnet adjacent to the dielectric layer.
